(19) United States
(12) Patent Application Publication
(10) Pub. No.: US 2001/0005144 A1
(43) Pub. Date: Jun. 28, 2001

(54) Configuration for testing a multiplicity of semiconductor chips

(76) Inventors: Robert Feurle, Neubiberg (DE); Dominique Savignac, Ismaning (DE)

Correspondence Address: Lerner and Greenberg, P.A., P.O. Box 2480, Hollywood, FL, 33022-2480, US

(21) Appl. No.: 09/748,531

(22) Filed: Dec. 26, 2000

(30) Foreign Application Priority Data
Dec. 23, 1999 (DE) 199 62 677.4

(51) Int. Cl. G01R 31/26

(52) U.S. Cl. 324/765

(57) ABSTRACT

The configuration allows for testing a multiplicity of semiconductor chips with respect to critical parameters on the wafer level. Each of the semiconductor chips on a semiconductor wafer is additionally provided with at least one option pad. The option pad allows access for a test program to the chip for separating out the semiconductor chips which do not correspond to predetermined requirements for critical parameters.

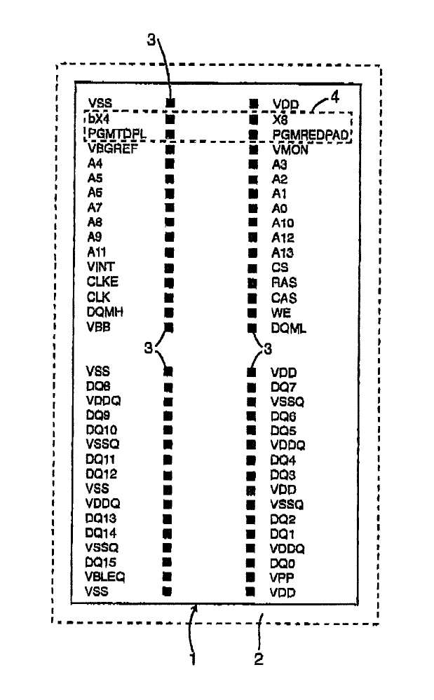

### BACKGROUND OF THE INVENTION

### FIELD OF THE INVENTION

The invention lies in the semiconductor technology field. More specifically, the invention relates to an configuration for testing a multiplicity of semiconductor chips with respect to critical parameters, by means of which semiconductor chips which do not fulfil predetermined requirements for these critical parameters can be singled out and separated.

Semiconductor chips must pass through a multiplicity of tests before they can be delivered to customers. In these tests, the semiconductor chips are examined with respect to various parameters which include, for example in the case of SDRAMs (DRAMs with synchronous clock control), so-called timing parameters such as, in particular, a so-called Tdpl test: the Tdpl test examines, after data have been written to a memory cell and potential has been removed from its word line, whether and how long the memory cell holds the data stored in it.

Depending on the manufacturer of a semiconductor wafer for the semiconductor chip, different values which, in each case, can be shorter or longer depending on the manufacturer, are obtained during the check of the individual semiconductor chips for these timing parameters.

To be able to guarantee, nevertheless, a uniform quality in view of this situation, design and test program for semiconductor chips have hitherto in each case been designed for the worst case with regard to such timing parameters so that customers can be supplied with semiconductor chips which correspond to the requirements set with regard to the timing parameters in every case.

Thus, semiconductor chips have hitherto been bonded individually in each case with respect to critical timing parameters and checked by means of a test set whether these semiconductor chips correspond to the requirements set with respect to the timing parameters. However, such a procedure is relatively expensive.

### SUMMARY OF THE INVENTION

The object of the present invention is therefore to provide a configuration for testing a multiplicity of semiconductor chips which overcomes the above-noted deficiencies and disadvantages of the prior art devices and methods of this general kind, and which provides the capability, even at wafer level, to examine the semiconductor chips with respect to different timing parameters so that it is possible to establish whether the respective semiconductor chip meets the requirements set for it.

With the above and other objects in view there is provided, in accordance with the invention, a testing configuration, comprising a multiplicity of semiconductor chips disposed on a semiconductor wafer, each of said semiconductor chips having at least one option pad for applying a test program to the respective said semiconductor chip, the test program testing whether or not the semiconductor chip fulfills predetermined requirements for critical parameters and wherein semiconductor chips that do not fulfill the predetermined requirements for the critical parameters can be separated out at wafer level.

In accordance with an added feature of the invention, the critical parameters are timing parameters. In a preferred embodiment, the timing parameter is a data holding time in memory cells of the semiconductor chip.

In other words, the objects of the invention as satisfied with a configuration of the type mentioned above in which the semiconductor chips of a semiconductor wafer in each case have at least one option pad via which a test program for separating out the semiconductor chips which do not fulfil the predetermined requirements for the critical parameters can be applied to the semiconductor chips at wafer level.

Accordingly, a check is carried out at wafer level to determine, without any great effort whether the respective semiconductor chip fulfils the requirements set for it with respect to the critical timing parameters. In other words, for each semiconductor chip, the option which is appropriate for it with respect to the timing parameters can be established at wafer level.

A preferred example for the critical parameters are, in particular, timing parameters which relate to the data holding time in memory cells of the semiconductor chip.

The novel configuration opens up the possibility, in particular, of being able to check, before critical parameters are permanently set, whether this is also possible in a test of the semiconductor chips without loss of yield.

Other features which are considered as characteristic for the invention are set forth in the appended claims.

Although the invention is illustrated and described herein as embodied in an configuration for testing a multiplicity of semiconductor chips, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of a specific embodiment when read in connection with the accompanying drawing FIGURE.

### BRIEF DESCRIPTION OF THE DRAWING

The drawing FIGURE is a top view of a semiconductor chip.

### DESCRIPTION OF THE PREFERRED EMBODIMENT

Referring now to the sole FIGURE of the drawing in detail there is seen a semiconductor chip 1. The chip 1 has a kerf 2 and contains a multiplicity of pads 3 via which, for example, supply voltage VDD, VBB, reference voltages VSS etc. can be supplied and voltages can be removed from the chip.

In addition, the semiconductor chip 1 also has pads bX4, X8, PGMTDPL and PGMREDPAD (framed by a dashed line 4) via which a test program can be applied to the semiconductor chip 1, at wafer level. That test program checks whether or not the semiconductor chip 1 fulfills the requirements set for it with respect to the critical timing parameters. Those semiconductor chips which do not satisfy these requirements are separated out.

The present invention therefore opens up the possibility of finally building up by bonding only those semiconductor chips which actually fulfil the requirements set for them with respect to the critical timing parameters such as, for example, Tdpl.

The important factor in the context of the present invention is, in particular, the checking of the semiconductor chips with regard to critical timing parameters already at wafer level, for which purpose separate pads (compare dashed line 4) are provided which allow test signals to be applied to the semiconductor chip 1 which “suggest” to the latter that it is in a bonded test mode in which it is checked with regard to its critical timing parameters. The configuration according to the invention, via the additionally provided option pads (compare dashed line 4), opens up the possibility of allowing a test program to run in a semiconductor chip which checks the latter with respect to the timing parameters.

In this configuration, the option pads (compare dashed line 4) are wired in the interior of the semiconductor chip 1 in such a manner that they allow the semiconductor chip to be tested with respect to the timing parameters. Using the PGMTDPL pad, “0” (VSS) or “1” (VCC) switches the timing parameter DPL, for example of a SDRAM semiconductor chip to one clock or two clocks. The parameter DPL can be tested more severely with one clock. Thus, these are static signals.

The configuration according to the invention thus opens up the possibility of rapidly checking, at wafer level, whether or not certain semiconductor chips fulfill the requirements set for them with respect to special critical timing parameters.

In the above exemplary embodiment, four pads (compare dashed line 4) are used for checking the semiconductor chip for critical timing parameters. Naturally, the number of these pads is not limited to four but can be greater or else smaller.

We claim:

1. A testing configuration, comprising a multiplicity of semiconductor chips disposed on a semiconductor wafer, each of said semiconductor chips having at least one option pad for applying a test program to the respective said semiconductor chip, the test program testing whether or not the semiconductor chip fulfills predetermined requirements for critical parameters and wherein semiconductor chips that do not fulfill the predetermined requirements for the critical parameters can be separated out at wafer level.

2. The configuration according to claim 1, wherein the critical parameters are timing parameters.

3. The configuration according to claim 2, wherein the timing parameter is a data holding time in memory cells of the semiconductor chip.
